(19) United States
(12) Patent Application Publication
(10) Pub. No.: US 2022/0262945 A1
(43) Pub. Date: Aug. 18, 2022

(54) SEMICONDUCTOR DEVICES WITH CLASS IV CHANNEL REGION AND CLASS III-V DRIFT REGION

(71) Applicant: SEMICONDUCTOR COMPONENTS INDUSTRIES, LLC, Phoenix, AZ (US)

(72) Inventors: Peter MOENS, Oudenaarde (BE); Tirthajyoti SARKAR, Fremond, CA (US)

(73) Assignee: SEMICONDUCTOR COMPONENTS INDUSTRIES, LLC, Phoenix, AZ (US)

(21) Appl. No.: 17/248,983

(22) Filed: Feb. 16, 2021

(51) Int. Cl. H01L 29/78; H01L 29/06; H01L 29/66

(52) U.S. Cl. CPC H01L 29/7813; H01L 29/66734; H01L 29/0611

(57) ABSTRACT

Diodes, transistors, and other devices having a class IV channel region and a class III-V drift region are described. The class IV channel region, such as a Si channel region, is able to provide all associated advantages, such as ease of manufacturing of many different types of devices, using cost-effective materials and techniques. Meanwhile, the III-V drift region provides substantially lower R_{on_sp} than a conventional class IV drift region, and substantially enhances the operational behaviors of resulting devices, without sacrificing other parameters, such as size or breakdown voltage.

### TECHNICAL FIELD

This description relates to semiconductor devices.

### BACKGROUND

Semiconductor devices include, for example, transistors, including multiple types of field effect transistors (FETs), with differing characteristics that are generally selected to be best-suited for specific use case scenarios. For example, a specific type of FET may be selected for a low, medium, or high voltage scenario. In other examples, FETs may be required to have a minimum switching speed, minimum thermal reliability, or low leakage currents.

Many efforts have been made to optimize FETs and other semiconductor devices, including attempts to optimize the above-referenced parameters (and others) for desired use cases, while simultaneously reducing a size and cost of the devices. However, such efforts may be limited by limitations of the materials being used, or of available manufacturing equipment. Moreover, attempts at further optimization that reach theoretical material limits may result in reductions in device operational characteristics or reliability.

### SUMMARY

According to one general aspect, a semiconductor device includes a substrate and a drift region formed on the substrate and comprising a class III-V material. The semiconductor devices includes a channel region comprising a class IV material formed on the drift region, wherein a current of the semiconductor device traverses the channel region, the drift region, and the substrate.

According to another general aspect, a semiconductor device includes a substrate and a drift region formed on the substrate and comprising a class III-V material. The semiconductor devices includes a channel region comprising a class IV material formed on the drift region, and a device structure of the semiconductor device is formed in the channel region and has at least one contact that initiates current flow through the channel region, to the drift region and to the substrate.

According to another general aspect, a method of making a semiconductor device includes forming a drift region using class III-V material and forming a channel region using class IV material. The method includes forming a device structure of the semiconductor device within the channel region.

The details of one or more implementations are set forth in the accompanying drawings and the description below. Other features will be apparent from the description and drawings, and from the claims.

### BRIEF DESCRIPTION OF THE DRAWINGS

FIG. 1 is a simplified view of a semiconductor device having a class IV channel region and a class III-V drift region.

FIG. 2 illustrates a side cross-sectional view of a transistor with a Silicon channel and a III-V drift region, according to example implementations.

FIG. 3 illustrates an alternate example implementation of the transistor of FIG. 1, with an inversion FET with a trench gate structure.

FIG. 4 illustrates an alternate example implementation of the transistor of FIG. 1, with an accumulation FET with a trench gate structure.

FIG. 5 illustrates first example operations for constructing the transistors of FIGS. 1-3.

FIG. 6 illustrates second example operations for constructing the transistors of FIGS. 1-3.

FIG. 7 is a flowchart illustrating example operations of FIGS. 5 and 6.

FIG. 8 is an example graph illustrating current-voltage characteristics of implementations of the transistors of FIGS. 1-4, compared to reference devices.

FIG. 9 is an example graph illustrating additional current-voltage characteristics of implementations of the transistors of FIGS. 1-4, compared to reference devices.

FIG. 10 is an example graph illustrating specific on-resistance and breakdown voltage characteristics of implementations of the transistors of FIGS. 1-4, compared to reference devices.

### DETAILED DESCRIPTION

Many semiconductor devices utilize a drift region that is designed, for example, to facilitate desired breakdown voltages of the devices, or otherwise manage off-state behavior of the devices. Although providing these and other advantages, such drift regions also exhibit a number of disadvantages, as well.

For example, a drift region exhibits a specific on-resistance (R_{on_sp}) that inhibits desired on-behavior of FETs and other types of devices. It is possible to lower R_{on_sp} by decreasing a device channel length, or by altering physical characteristics of the drift region (e.g., a size or doping profile thereof), but doing so may lead directly to other design difficulties, such as an overall larger device, increasing device capacitances, or reducing the desired advantages of the drift region.

The present disclosure describes diodes, transistors, and other devices having a class IV channel region and a class III-V drift region. For example, examples of such devices may have a Silicon (Si) channel region, and a Gallium Arsenide (GaAs) drift region.

The class IV channel region, such as a Si channel region, is able to provide all associated advantages, such as, e.g., ease of manufacturing of many different types of devices, using cost-effective materials and techniques. Meanwhile, the III-V drift region provides substantially lower R_{on_sp} than a conventional class IV drift region, and therefore substantially enhances the operational behaviors of resulting devices, without sacrificing other parameters, such as size or breakdown voltage.

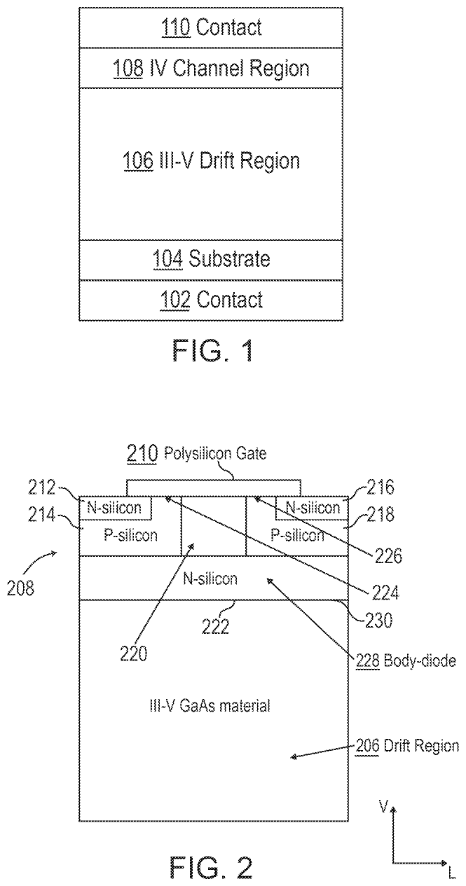

FIG. 1 is a simplified view of a semiconductor device having a class IV channel region and a class III-V drift region. In the example of FIG. 1, a first contact 102 is illustrated as having a substrate 104 disposed thereon. For example, the substrate 104 may be formed of a class III-V material.

A class III-V drift region 106 is disposed on the substrate 104. A class IV channel region 108 is disposed on the class III-V drift region 106, and a second contact 110 is disposed on the class IV channel region 108. The channel region 108 should be understood to represent, or refer to, any region formed using the class IV material in which a current channel or current channel area may be formed, or in which current or current flow is initiated that traverses into the class III-V drift region 106 to the substrate 104. Thus, as described in detail, below, the class IV channel region 108 may include a device structure(s) of the semiconductor device of FIG. 1, including, e.g., a source region or gate structure of a transistor.

In the various examples described herein, the phrase class III-V material and related terms may be understood to represent any potential combination of one or more group or class III elements (including, e.g., Al, Ga, In) with one or more group or class V elements (e.g., N, P, As, or Sb), including combinations with either whole or fractional molecular weights. Thus, example class III-V materials may include, e.g., GaAs, InP, GaP, and GaN, AlN, as well as ternary combinations e.g. AlGaN, AlInN, AlGaAs and quartery combinations e.g. InAlGaN or AlInGaAs.

As FIG. 1 is a simplified representation of many different types of semiconductor devices, it will be appreciated that the illustrated components of FIG. 1 may be implemented using various types of materials and/or structures. Moreover, various additional or alternative layers or other components, not specifically illustrated in FIG. 1, may be included.

The various layers and components may be disposed in various relations to one another. For example, the contact 110 is illustrated as being disposed on the class IV channel region 108, but, in some implementations, the contact 110 may be disposed at least partially within the class IV channel region 108. In general, the various layers are not required to completely cover underlying layers. For example, the contact 110 need not completely cover an entirety of the class IV channel region 108.

Thus, the semiconductor device of FIG. 1 may represent a number of different types of semiconductor devices. For example, the device of FIG. 1 may represent a Schottky diode, such as when the contact 110 is a metal Schottky contact, and forward-bias current flow occurs between the contact 110 (providing an anode of the Schottky diode) and the contact 102 (providing a cathode of the Schottky diode).

In other examples, the device of FIG. 1 may represent a field effect transistor (FET), in which case the contact 110 may represent a gate contact and/or a source contact of the FET, while the contact 102 may represent a drain contact. As described and illustrated below, e.g., with respect to FIGS. 2-4, many different types of FETs may be constructed using the structure of FIG. 1. As such FETS and other devices are formed in the class IV channel region 108 (e.g., in Silicon, or Germanium), many or all known or future manufacturing techniques for manufacturing devices in such materials may be used, and associated advantages may be obtained. For example, in the context of metal-oxide-semiconductor (MOS) FETs, Si is well-known to provide desirable channel properties and oxide interface properties with respect to the included gate oxide.

In addition, in all such implementations, the class III-V drift region 106 provides a number of advantages. For example, the class III-V drift region 106 has a higher mobility and correspondingly lower resistance (lower R_{on_sp}) than the class IV channel region. For example, a class III-V material such as GaAs may have a resistance that is at least ten times less than a resistance of Si. For example, in conventional low voltage MOSFET devices (e.g., with a rated breakdown voltage below 50V), half of an overall on-resistance may occur within a conventional drift region, so that reducing the drift region resistance by a factor of ten imparts a significant overall gain in resistance. Moreover, devices rated for higher operational voltages tend to experience a higher percentage of overall on resistance within a drift region as the operational voltages increase, so that such devices benefit even further from the use of the class III-V drift region 106.

Further, the III-V drift region 106 will typically have a conduction band energy level that is lower than a conduction band energy level of the class IV channel region 108. In other words, a conduction band offset may be provided at an interface between the class IV channel region 108 and the class III-V drift region 106. This conduction band offset provides a de facto body diode, referred to herein as a conduction band diode, because electrons traversing the interface experience no barrier when moving from the higher to the lower conduction band energy level (e.g, from the class IV channel region 108 toward the contact 102), but experience a voltage barrier in the reverse direction (corresponding to the conduction band offset or energy gap).

In general, body diodes in power MOSFETs may be useful, for example, in reducing or eliminating voltage spikes that may occur in the presence of an inductive load, or otherwise managing device voltages during switching behaviors. Some types of existing power MOSFETs have well-formed body diodes, in which case the described conduction band diode added using the techniques described herein may contribute to the existing body diode.

In other power FET devices, however, a body diode may be ineffective or non-existent. For example, a conventional accumulation FET, described below with respect to FIG. 4, typically does not have a body diode. As a result, the conduction band diode described herein provides a previously-unavailable diode structure for such devices that may be used to provide the benefits of body diodes found in other types of power MOSFET devices.

Additionally, when the device of FIG. 1 represents a Schottky diode, the conduction band diode reduces off-state leakage that may otherwise occur in the presence of a drift region electric field. Put another way, the class III-V drift region 106 may sustain a higher electric field in reverse-bias than a comparable, conventional Schottky device, which prevents or reduces leakage currents that may otherwise occur in such devices.

Still further, the conduction band diode may be adjusted or tuned to define a desired voltage offset within a range of available voltage offsets. For example, such tunability may be achieved by selection of different materials from class III, class IV, and/or class IV. Additionally, tunability may be achieved by adjusting relative proportions of the class III and class V materials within the III-V drift region 106. Thus, for example, different III-V alloys may be combined, at desired ratios, to obtain desired results. For example, Aluminum Gallium Arsenide may be used as AlₓGa₁₋ₓAs, where x indicates a number between 0 and 1 to indicate the alloy between GaAs and AlAs being used.

FIG. 2 illustrates a side cross-sectional view of a transistor with a Silicon channel and a III-V drift region, according to example implementations. In FIG. 2, a drift region 206 may include a III-V drift region formed using, e.g., GaAs. A channel region 208 is disposed on the III-V drift region 206. In the example of FIG. 2 the channel region 208 is formed using Si.

In FIG. 2, the illustrated device is a field-effect transistor (FET), which includes a gate 210 (e.g., a polysilicon gate), as well as source region 212 and source region 216. The gate 210, the source region 212, and the source region 216 may have separate contacts, not illustrated in the simplified example of FIG. 2. The source regions 212, 216 are doped to have a first conductivity type, which, in the example of FIG. 2, is n-type.

A region 214 and a region 218 are doped to have a second conductivity type, which, in the example of FIG. 2, is p-type. The regions 214, 218 may be referred to as body regions, or p-type body regions, or p-body regions. A region 220 is disposed under the gate 210 and between the source regions 212, 216, while a region 222 is disposed between the III-V drift region 206 and the regions 214, 218, 220, as shown. Both regions 220 and 222 are doped to have a first conductivity type, which, in the example of FIG. 2, is n-type.

In FIG. 2, by way of convention and as illustrated by the included legend, a vertical direction V is considered to be defined along an axis that traverses, e.g., the III-V drift region 206, the region 222, the region 220, and the gate 210. A lateral direction L is perpendicular to the V axis, and traverses, e.g., the region 222.

Therefore, an applied gate-source voltage V_{GS} causes an inversion layer that enables lateral current flow through a lateral channel area 224 and a lateral channel area 226. As shown, the lateral channel area 224 is defined between the source 212 and the region 220, through the region 214. Similarly, the lateral channel area 226 is defined between the source 216 and the region 220, through the region 218. Both resulting lateral current flows then proceed vertically through the regions 220, 222 and through the III-V drift region 206, to a drain contact (similar to contact 102 of FIG. 1, not separately illustrated in FIG. 2).

FIG. 2 thus provides non-limiting examples of possible transistor structures that may be implemented using the techniques described herein. For example, the structure of FIG. 2 may be implemented in a stripe pattern. In other examples, the structure of FIG. 2 may be implemented in a circular pattern (in which case, e.g., the source regions 212, 216 may be formed as a single, circular source region that is shown in cross section in FIG. 2, with similar comments applying to the regions 214, 218).

In these and various other examples, structures and operations of resulting transistor structures may be implemented using any known or future techniques, while utilizing all of the advantages of forming such transistor structures in Si. For example, as referenced herein, use of Si and associated processing techniques enables cost-effective construction of many different types of transistor structures, having well-known and well-understood properties (including, e.g., interface properties between the Si and a gate oxide of the gate 210, as well as channel properties of the lateral channel areas 224, 226).

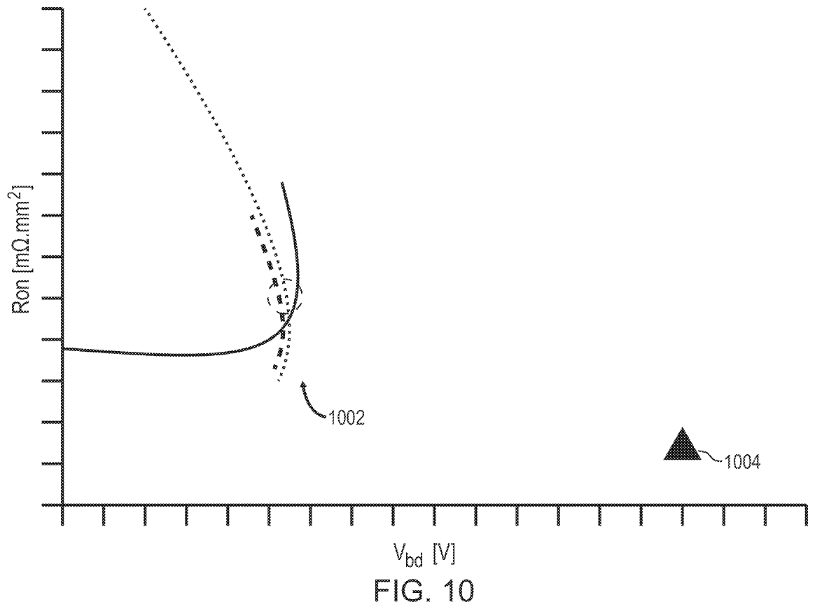

In addition, as also described above, the III-V drift region 206 provides a number of additional advantages. In particular, the relatively higher carrier mobility and lower resistance of the III-V drift region 206, as compared to the Si channel region 208, facilitates improved on-state characteristics, including faster switching speeds. Additionally, a breakdown voltage of the device may be substantially improved (as illustrated, for example, in the graph of FIG. 10).

In FIG. 2, a body diode 228 is formed at the PN junction of the regions 214, 218 and the region 222. In addition, a conduction band diode 230 is formed at the interface of the region 222 and the III-V drift region 206, due to the conduction band offset that occurs at that interface, as described above. As a result, operations of the body diode 228 are enhanced by the presence and operations of the conduction band diode 230.

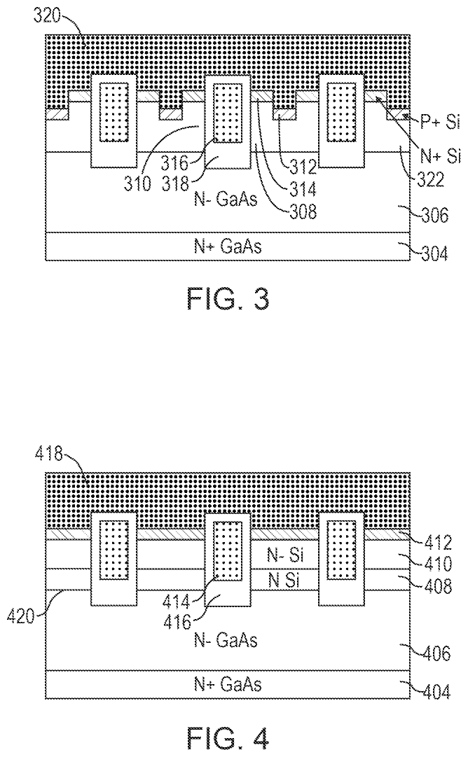

FIG. 3 illustrates an alternate example implementation of the transistor of FIG. 1, with an inversion FET with a trench gate structure. In FIG. 3, a III-V substrate 304 is illustrated, with a III-V drift region 306 disposed thereon. A first Si layer 308 of a first conductivity type (e.g., n-type) is formed on the III-V drift region 306, and a second Si layer 310 of a second conductivity type (e.g., p-type) is formed on the first Si layer 308. Heavily-doped regions 312 of the second conductivity type and heavily-doped regions 314 of the first conductivity type (providing source regions for the transistor structures) are formed on the second Si layer 310, as shown.

A polysilicon trench gate 316 is formed within a gate oxide 318, and the resulting gate structures are disposed within the first Si layer 312, the second Si layer 314, and between the heavily-doped regions 314, with the gate oxide 318 extending into the III-V drift region 306. In another implementation, the trench gate may not extend into the III-V drift region 306, but rather may stop at the first Si layer 308. A source contact 320 is disposed over the regions 312, 314, and over the trench gate structures 316, 318.

Operations of the structure of FIG. 3 are very similar conceptually to the operations of the device of FIG. 2. Specifically, an applied V_{GS} creates an inversion layer in the p-type layer 310, between the heavily-doped n-type regions 314 and the n-type layer 308, and adjacent to the various gate structures 316, 318. Current flow may thus proceed through the Si channel area as just described, and vertically through the III-V drift region 306 to the III-V substrate 304.

Accordingly, all of the advantages described herein are provided with respect to the structure of FIG. 3. In particular, an on-resistance of the illustrated device is improved (lowered), as compared to a corresponding on-resistance of a comparable device using a conventional class IV drift region.

Further, in addition to a body diode formed at the PN interface of the layers 310/308, a conduction band diode 322 is formed at the interface between the Si layer 308 and the III-V drift region 306. Consequently, as described herein, the various advantages of an enhanced body diode may be obtained, including, e.g., improved breakdown voltage of the device.

FIG. 4 illustrates an alternate example implementation of the transistor of FIG. 1, with an accumulation FET with a trench gate structure. In FIG. 4, a III-V substrate 404 is illustrated, with a III-V drift region 406 disposed thereon. A first Si layer 408 of a first conductivity type (e.g., n-type) is formed on the III-V drift region 406. Then, a second Si layer 410 that is lightly-doped with dopants of the first conductivity type is formed on the first Si layer 408. A heavily-doped third Si layer 412 of the first conductivity type is formed on the second Si layer 410.

Similar to FIG. 3, a polysilicon trench gate 414 and surrounding gate oxide 416 may be formed in the Si layers 408, 410, 412, with the gate oxide 416 extending into the III-V drift region 406. In another implementation, the trench gate 414 may not extend into the III-V drift region 406, but rather may stop at the first Si layer 408. Also similar to FIG. 3, a contact 418 is disposed over the gate structures 414, 416, and over the third Si layer 412.

In general, operation of the structure of FIG. 4 relies on application of V_{GS} to enable accumulation of electrons along the trench gate structures 414, 416 and through a channel region that includes the lightly-doped second Si layer 410, and then vertically through the III-V drift region 406 to the III-V substrate 404. Alternatively, the device may be turned off (no current flow), e.g., by grounding the gate structure 414, 416 and thereby depleting the lightly-doped second Si layer 410 to create a pinch-off condition.

Thus, the example of FIG. 4 provides the types of improvements in on-resistance and breakdown voltages as described herein. In addition, the example of FIG. 4 provides a conduction band diode at an interface 420 between the first Si layer 408 and the III-V drift region 406.

In particular, the device of FIG. 4 does not provide a body diode, because all of the Si layers 408, 410, 412 are doped with the same, first conductivity type, so that no PN junction is present. Consequently, conventional implementations of such trench gate accumulation FETs are not afforded the advantages of a body diode. However, the example of FIG. 4 provides a trench gate accumulation FET structure that also benefits from inclusion of the conduction band diode created at the Si/III-V interface 420.

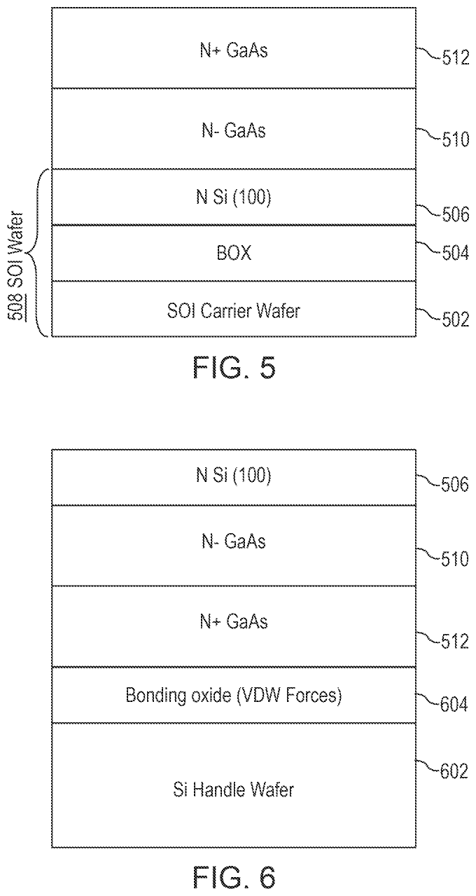

FIGS. 5 and 6 illustrate example operations for constructing the transistors of FIGS. 1-3. In FIG. 5, a Silicon-on-Insulator (SOI) carrier wafer 502 has a buried oxide (BOX) layer formed thereon. A Si layer 506 is formed on the BOX layer 504. Together, the SOI carrier wafer 502, the BOX layer 504, and the Si layer 506 may be referred to as a SOI wafer 508.

In the example of FIG. 5, a GaAs layer 510 is grown on the Si layer 506. For example, the GaAs layer 510 may be a lightly-doped, n-type layer of GaAs. A second GaAs layer 512 is formed on the first GaAs layer 510. For example, the GaAs layer 512 may be a heavily-doped, n-type layer of GaAs.

In FIG. 6, the Si layer 506, the lightly-doped GaAs layer 510, and the heavily doped GaAs layer 512 are bonded, using a bonding oxide 604, to a Si handle wafer 602, and flipped. Subsequently, the SOI carrier wafer and BOX oxide are removed.

As a result, in FIG. 6, the Si layer 506 is made available and ready for further processing. For example, any of the transistor and/or diode structures of FIGS. 1-4 may be formed therein.

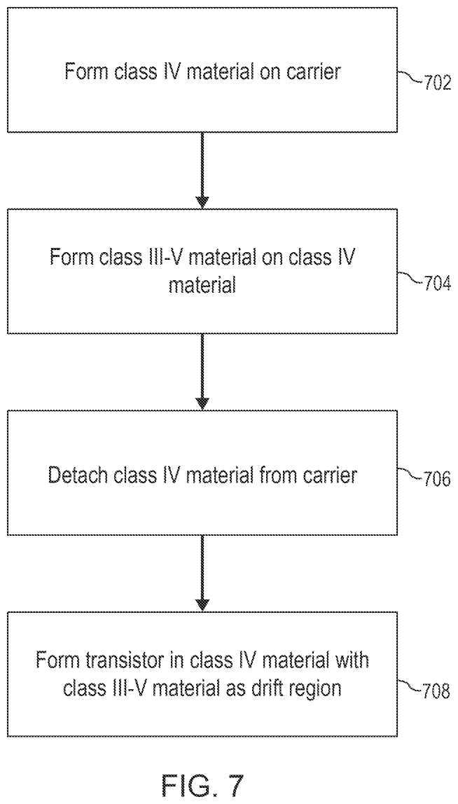

FIG. 7 is a flowchart illustrating example operations of FIGS. 5 and 6. As shown, and as understood from the example of FIG. 5, a class IV material may be formed on a carrier (702). For example, a standard layer of Si may be formed on any available or suitable carrier wafer.

A class III-V material may be formed on the class IV material (704). For example, GaAs may be grown on Si, using a number of techniques. For example, any of molecular beam epitaxy (MBE), Metal-Organic Chemical Vapor Deposition (MOCVD). or Hydride vapour phase epitaxy (HVPE) may be used.

Then, the class IV material may be detached from the carrier (706), with the class III-V material being attached thereto. A transistor (or other device) may be formed in the class IV material, with the class III-V material used to provide a drift region for the transistor (708). For example, the structure of FIG. 5 may be flipped and bonded to a new carrier or handle wafer, and then the original carrier wafer may be removed, leaving the class IV material exposed for further processing, while the class III-V material bonded to the new carrier or handle wafer.

In further operations, not explicitly illustrated in FIG. 7, the second carrier or handler wafer (and any intervening bonding oxide) may be removed. For example, suitable grinding and etching techniques may be used. For example, the BOX layer 504 may be used as an etch stop layer, so that definition of the Si layer 506 may be very well controlled, and a large, thin Si layer is provided.

In various example implementations of the process of FIG. 7, the operations 702-708 may be performed in a different order than that shown, and additional or alternative operations may be included. For example, a Si layer may be formed with all desired device structures formed therein. Then, a layer of GaAs may be grown thereon to serve as a drift region, using, e.g., a low temperature MBE process. Such an approach may be suitable, for example, when only relatively thin layers of GaAs are required.

In still other implementations, Si may be grown directly on GaAs. Then, subsequent device processing may proceed using the formed Si. For example, Si may be grown on GaAs using atomic layer deposition (ALD) techniques.

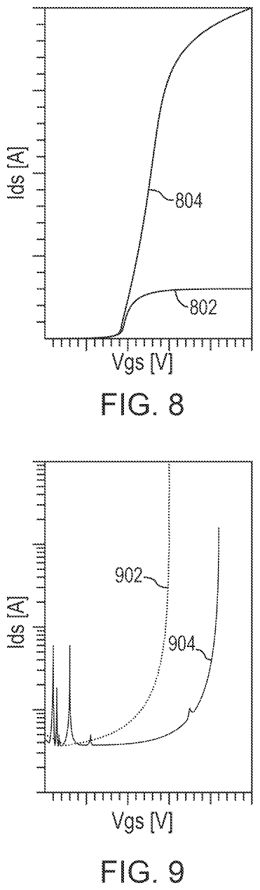

FIGS. 8 and 9 are example graphs illustrating drain current-gate voltage characteristics of implementations of the transistors of FIGS. 1-4, compared to reference devices. For example, in FIG. 8, a line 802 may represent a standard Si accumulation FET, while a line 804 represents an accumulation FET as described above, with respect to FIG. 4. As shown, the implementation of FIG. 4 exhibits considerably higher I_{DS} (forward current), across a range of V_{GS} values.

FIG. 9 illustrates example breakdown characteristics. In FIG. 9, a line 902 represents the reference Si accumulation device, while the line 904 may correspond to an implementation of FIG. 4. As shown, the implementation of FIG. 4 exhibits a higher breakdown voltage.

FIG. 10 is an example graph illustrating specific on-resistance and breakdown voltage characteristics of implementations of the transistors of FIGS. 1-4, compared to reference devices. In FIG. 10, the various reference devices are illustrated using plot points 1002, while plot point 1004 corresponds to an implementation of FIGS. 1-4. FIG. 10 illustrates that the implementations of FIGS. 1-4 exhibit significantly lowered values of on-resistance, while at the same time providing increases in breakdown voltage.

Thus, described techniques enable reductions in on-resistance of various diodes, transistors, and other devices, with improvements in breakdown voltage, as well, and without compromising other performance parameters of such devices. Resulting devices enable use of high current applications with a lower power loss, and with relatively fewer requirements for parallel processing. For example, cloud computing providers may be enabled to provide significantly increased cloud computing resources to customers, without requiring increased server parallelization and/or reduced heat-sinking arrangement.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor device, comprising:
a substrate;
a drift region formed on the substrate and comprising a class III-V material; and
a channel region comprising a class IV material formed on the drift region, wherein a current of the semiconductor device traverses the channel region, the drift region, and the substrate.

2. The semiconductor device of claim 1, further comprising:
a first contact to which the substrate is attached; and
a second contact to which the channel region is attached

3. The semiconductor device of claim 2, wherein the semiconductor device comprises a Schottky diode, and further wherein the second contact is a metal Schottky contact providing an anode of the Schottky diode, the channel region includes n-type Silicon, the drift region is doped n-type, and the first contact provides a cathode of the Schottky diode.

4. The semiconductor device of claim 2, wherein the semiconductor device comprises a field-effect transistor (FET), and further wherein the first contact provides a drain contact of the FET, the second contact provides a source contact of the FET, and the channel region includes at least one source region defining a current channel of the current.

5. The semiconductor device of claim 4, wherein the FET includes a trench gate inversion FET.

6. The semiconductor device of claim 4, wherein the FET includes a trench gate accumulation FET.

7. The semiconductor device of claim 1, wherein the class IV material includes Silicon, and the class III-V material includes Gallium Arsenide.

8. The semiconductor device of claim 1, wherein the substrate is formed using the class III-V material.

9. The semiconductor device of claim 1, wherein a conduction band diode is formed at an interface between the channel region and the drift region and defined by a conduction band offset between the class IV material and the class III-V material.

10. A semiconductor device, comprising:
a substrate;
a drift region formed on the substrate and comprising a class III-V material;
a channel region comprising a class IV material formed on the drift region; and
a device structure of the semiconductor device formed in the channel region and having at least one contact that initiates current flow through the channel region, to the drift region and to the substrate.

11. The semiconductor device of claim 10, wherein the semiconductor device comprises a Schottky diode, and further wherein the at least one contact includes a metal Schottky contact providing an anode of the Schottky diode, and the substrate is disposed on at least a second contact providing a cathode of the Schottky diode.

12. The semiconductor device of claim 10, wherein the semiconductor device comprises a field-effect transistor (FET), and further wherein the device structure includes at least one source region defining a current channel of the current flow, the at least one contact includes a gate contact and a source contact connected to the at least one source region, and a drain contact is connected to the substrate.

13. The semiconductor device of claim 12, wherein the FET includes a trench gate inversion FET.

14. The semiconductor device of claim 12, wherein the FET includes a trench gate accumulation FET.

15. The semiconductor device of claim 10, wherein a conduction band diode is formed at an interface between the channel region and the drift region and defined by a conduction band offset between the class IV material and the class III-V material.

16. The semiconductor device of claim 1, wherein the substrate is formed using the class III-V material.

17. A method of making a semiconductor device, comprising:
forming a drift region using class III-V material;
forming a channel region using class IV material; and
forming a device structure of the semiconductor device within the channel region.

18. The method of claim 17, comprising:
forming the class III-V material on the class IV material, while the class IV material is disposed on a first carrier;
attaching the class III-V material to a second carrier;
detaching the class IV material from the first carrier; and
providing the device structure within the channel region while the class III-V material is attached to the second carrier.

19. The method of claim 17, comprising:
forming the device structure within a first surface of the class IV material; and
forming the class III-V material on a second surface, opposed to the first surface, subsequent to the providing the device structure.

20. The method of claim 17, wherein the device structure includes a field effect transistor (FET) device structure.
